(19) United States
(12) Patent Application Publication
(10) Pub. No.: US 2010/0190341 A1
(43) Pub. Date: Jul. 29, 2010

(54) APPARATUS, METHOD FOR DEPOSITING THIN FILM ON WAFER AND METHOD FOR GAP-FILLING TRENCH USING THE SAME

(75) Inventors: Sang-Jun Park, Kyungki-do (KR); Chang-Hee Han, Chungbuk (KR); Ho-Young Lee, Daejeon (KR); Seong-Hoe Jeong, Chungnam (KR)

Correspondence Address: LADAS & PARRY LLP, 224 SOUTH MICHIGAN AVENUE, SUITE 1600, CHICAGO, IL, 60604, US

(73) Assignee: IPS LTD., Kyungki-do (KR)

(21) Appl. No.: 12/669,498

(22) PCT Filed: Jul. 14, 2008
(86) PCT No.: PCT/KR08/04131

§ 371 Date: Jan. 18, 2010

(30) Foreign Application Priority Data
Jul. 19, 2007 (KR) 10-2007-0072052

(51) Int. Cl. H01L 21/465

(52) U.S. Cl. 438/694; 156/345.1; 156/345.33; 257/E21.46; 257/E21.485

(57) ABSTRACT

Provided are an apparatus and method for depositing a thin film, and a method for gap-filling a trench in a semiconductor device. The thin film depositing apparatus includes a plurality of substrates provided on the same space inside a reactor, wherein deposition of the thin film and partial etching of the deposited thin film are repeated to form the thin film on the plurality of substrates by exposing the substrates to two or more source gases and an etching gas supplied together at predetermined time intervals while rotating the substrates. According to exemplary embodiments, it is possible to concurrently or alternatively perform deposition and etching of a thin film, so that a thin film with good gap-fill capability can be deposited.

### TECHNICAL FIELD

The present disclosure relates to an apparatus and method for depositing a thin film on a wafer and a method for gap-filling a trench, and more particularly, to an apparatus and method for depositing a thin film for a gap-fill process, and a gap-fill method for a semiconductor device.

### BACKGROUND ART

A Semiconductor device manufacturing processes generally start with a process of forming a MOS transistor on a semiconductor substrate. The process of forming the MOS transistor is performed using a shallow trench isolation (STI). In a related art STI process, a trench filling oxide is typically formed by using chemical vapor deposition (CVD). However, in a narrow pattern with a large aspect ratio, gap-filling using such an oxide formed with CVD has limitations.

To solve the gap-fill issue, a high density plasma (HDP)-CVD using a gas such as silane (SiH₄) or a sub-atmospheric (SA)-CVD, in which liquid such as tetra ethyl ortho silicate (TEOS) is vaporized and reacted, have been recently used.

HDP-CVD, a type of CVD, in which deposition and etching are repeated, is employed by many device manufacturers due to its high productivity. To obtain high gap-fill capability, HDP-CVD requires a low deposition rate and a high etching rate, which causes the problem of a lower layer being undesirably etched also. To solve this problem, a recipe with a wide allowable range may be used. However, this method may also cause etching of a lower layer due to non-uniformity of mass-produced reactors. SA-CVD using an O₃-TEOS reaction has advantages in that substrate damage does not occur because of a thermal CVD technique and widely used O₃ and TEOS are employed. However, SA-CVD is problematic in that it has a low deposition rate. Also, it is being reported that even with the use of O₃-TEOS oxide or HDP-CVD oxide in a gigabyte DRAM device having a depth of 0.25 m and a width of 0.1 m or less, the possibility of void formation is very high in trench.

To solve the above problems, an atomic layer deposition (ALD) method has been introduced. The ALD method is a thin film forming method in which a thin film is formed by a surface saturation of source gases, where the respective source gases are supplied separately.

However, when the number of source gas types in the ALD method increases, a complicated gas supply line and a plurality of valves for controlling the gas supply line must be established in order to supply the source gases into a reactor. Accordingly, problems of increased cost for establishing the gas supply line and the valves and having to secure a space for establishing the gas supply line and the valves result. Also, capacitances of hardware and software for controlling the supply of source gases should be increased. Furthermore, since the respective aloads of the source gases supplied into the reactor do not all correspond to the aload of a purge gas, the pressure in the reactor is irregularly changed, possibly causing process instability.

The complexity and frequent operation of the valves shorten their life cycles, increase the maintenance cost of the apparatus, and increase the downtime of the apparatus by adding to the maintenance requirements of the apparatus, thereby reducing productivity.

To overcome the above problems, U.S. Pat. No. 5,730,802 discloses an apparatus and method for depositing a thin film in which a reactor is separated by partition plates, a first material gas, a second material gas, and a separation gas are supplied into spaces of the reactor separated by the partition plates through gas supply inlets, and an atomic layer is formed while a substrate holder rotates.

The construction of the apparatus for depositing a thin film disclosed in the above US patent is shown in FIG. 1.

Referring to FIG. 1, the apparatus for depositing a thin film includes a reactor 10, a substrate holder 20 provided rotatable in the reactor 10, material gas supply inlets 30 and 40, a separation gas supply inlet 50, and a partition plate 60 for preventing material gases from being mixed. While material gases and a separation gas are respectively supplied onto a substrate (W) through the material gas supply inlets 30 and 40 and the separation gas supply inlet 50 by rotation of the substrate holder 20, atomic layer deposition is performed.

With high integration of semiconductor devices due to advances in semiconductor manufacturing technologies, the line width and intervals between lines on a circuit are downscaled. Therefore, a gap-fill process, which can completely fill a trench having an increased aspect ratio, is required. Although the above-configured the apparatus for depositing a thin film 1 makes performing atomic layer deposition under high aspect ratio conditions basically possible, it is limited in its ability to gap-fill a trench having a very high aspect ratio.

### DISCLOSURE OF INVENTION

### Technical Problem

The present disclosure provides an apparatus for depositing a thin film with good ga p-fill capability using a simple process.

The present disclosure also provides a method for depositing a thin film with good gap-fill capability.

The present disclosure also provides a method for gap-filling a trench with good gap-fill capability.

### Technical Solution

According to an exemplary embodiment, an apparatus for depositing a thin film includes: a reactor; and a plurality of substrates provided on the same space inside the reactor, wherein deposition of the thin film and partial etching of the deposited thin film are repeated to form the thin film on the plurality of substrates by exposing the plurality of substrates to two or more source gases and an etching gas supplied together at predetermined time intervals while rotating the plurality of substrates.

The apparatus may include: a substrate supporting plate provided with a plurality of substrate loading parts on which the plurality of substrate are loaded, and rotatably installed inside the reactor; and a gas injection assembly provided over the substrate supporting plate in the reactor to inject a gas onto the substrate supporting plate and including a plurality of gas injection units arranged radially, wherein the plurality of gas injection units comprise at least one first source gas injection unit configured to inject a first source gas onto the substrate supporting plate, at least one second source gas injection unit configured to inject a second source gas that is different from the first source gas onto the substrate supporting plate, at least one etching gas injection unit configured to inject an etching gas for etching a thin film deposited by the first source gas and the second source gas onto the substrate supporting plate, and at least one purge gas injection unit configured to inject a purge gas for purging the first source gas, the second source gas and the etching gas onto the substrate supporting plate.

According to another exemplary embodiment, a method for depositing a thin film includes: (a1) loading a plurality of substrates on a substrate supporting plate provided with a plurality of substrate loading parts and rotatably installed inside a reactor; (a2) rotating the substrate supporting plate such that the plurality of substrates are sequentially exposed to a first source gas injection block, a purge gas injection block, a second source gas injection block, a purge gas injection block, an etching gas injection block and a purge gas injection block, which are arranged radially; (a3) depositing a thin film by supplying a first source gas, a second source gas, a purge gas and an etching gas onto the substrate supporting plate together through each of the gas injection blocks.

According to yet another exemplary embodiment, a method for depositing a thin film includes: (b1) loading a plurality of substrates on a substrate supporting plate provided with a plurality of substrate loading parts and rotatably installed inside a reactor; (b2) rotating the substrate supporting plate such that the plurality of substrates are sequentially exposed to a first source gas injection block, a purge gas injection block, a second source gas injection block, a purge gas injection block, an etching gas injection block and a purge gas injection block, which are arranged radially; (b3) depositing a thin film by supplying a first source gas, a second source gas and a purge gas onto the substrate supporting plate together through the first source gas injection block, the second source gas injection block and the purge gas injection block; (b4) after the thin film is deposited at a predetermined thickness, stopping the supply of the first source gas and the second source gas, and supplying an etching gas through the etching gas injection block to etch the deposited thin film; (b5) after an elapse of a predetermined time, stopping the supply of the etching gas and supplying the first source gas and the second source gas onto the substrate supporting plate through the first source gas injection block and the second source gas injection block to deposit the thin film; and (b6) sequentially repeating the operation (b4) and the operation (b5) at least once.

According to a further yet another exemplary embodiment, a method for gap-filling a trench or gap formed on a substrate is performed by depositing a thin film on the substrate using the above thin film depositing method, wherein deposition and etching are concurrently or alternatively performed using an oxide or nitride forming source as the first source gas, an oxygen-containing gas or a nitrogen-containing gas as the second source gas, and an oxide or nitride etching gas as the etching gas to form a first oxide layer or first nitride layer in the trench or gap formed on the substrate.

According to still another exemplary embodiment, a method for gap-filling a contact hole or via hole formed on a substrate is performed by depositing a thin film on the substrate using the above thin film depositing method, wherein deposition and etching are concurrently or alternatively performed using a metal source gas as the first source gas, a reaction gas as the second source gas and a metal etching or metal nitride etching gas as the etching gas to form a metal layer or metal nitride layer in the contact hole or via hole formed on the substrate.

### ADVANTAGEOUS EFFECTS

According to exemplary embodiments, it is possible to concurrently or alternatively perform deposition and etching of a thin film, so that a thin film with good gap-fill capability can be deposited. Also, the apparatus for depositing a thin film according to the present invention does not require frequent operation of valves while atomic layer deposition is performed, and can reduce waste of source gases, and therefore increase productivity.

### BRIEF DESCRIPTION OF THE DRAWINGS

FIG. 1 is a schematic view of an apparatus for depositing a thin film having a rotatable substrate holder according to a related art;

FIG. 2 is a schematic view of an apparatus for depositing a thin film according to an exemplary embodiment;

FIG. 3 is a sectional view illustrating a substrate supporting plate of an apparatus for depositing a thin film according to an exemplary embodiment and is a sectional view taken along line III-III of FIG. 2;

FIG. 4 is a sectional view illustrating a gas injection assembly of an apparatus for depositing a thin film according to an exemplary embodiment and is a sectional view taken along line IV-IV of FIG. 2;

FIG. 5 is a sectional view illustrating a gas injection assembly of an apparatus for depositing a thin film according to another exemplary embodiment and is a sectional view taken along line IV-IV of FIG. 2;

FIG. 6 is a sectional view illustrating a gas injection unit of a gas injection assembly of an apparatus for depositing a thin film according to an exemplary embodiment and is a sectional view taken along line V-V of FIG. 4;

FIG. 7 is a flowchart illustrating a method for depositing a thin film according to an exemplary embodiment;

FIG. 8 is a flowchart illustrating a method for depositing a thin film according to another exemplary embodiment;

FIGS. 9 through 11 are graphs showing flow rates of first source gas, second source gas, etching gas and purge gas versus time according to an exemplary embodiment;

FIG. 12 is a graph showing a thin film forming process in which deposition and etching are alternatively performed according to an exemplary embodiment;

FIG. 13 is a schematic sectional view of a substrate having a trench;

FIG. 14 is a schematic sectional view illustrating a process of depositing an oxide layer in a trench formed on a substrate using a thin film depositing method according to an exemplary embodiment;

FIG. 15 is a schematic sectional view illustrating a process of depositing an additional oxide layer on the oxide layer formed in a trench using a thin film depositing method according to an exemplary embodiment;

FIG. 16 is a schematic sectional view illustrating a method for gap-filling a trench in a semiconductor device using a thin film depositing method according to an exemplary embodiment;

FIG. 17 is a schematic view illustrating a status before an etching gas is supplied when gap-filling a trench using a thin film depositing method according to an exemplary embodiment;

FIG. 18 is a schematic view illustrating a status after an etching gas is supplied when gap-filling a trench using a thin film depositing method according to an exemplary embodiment; and

FIG. 19 is a flowchart illustrating a method for gap-filling a trench in a semiconductor device using a thin film depositing method according to an exemplary embodiment.

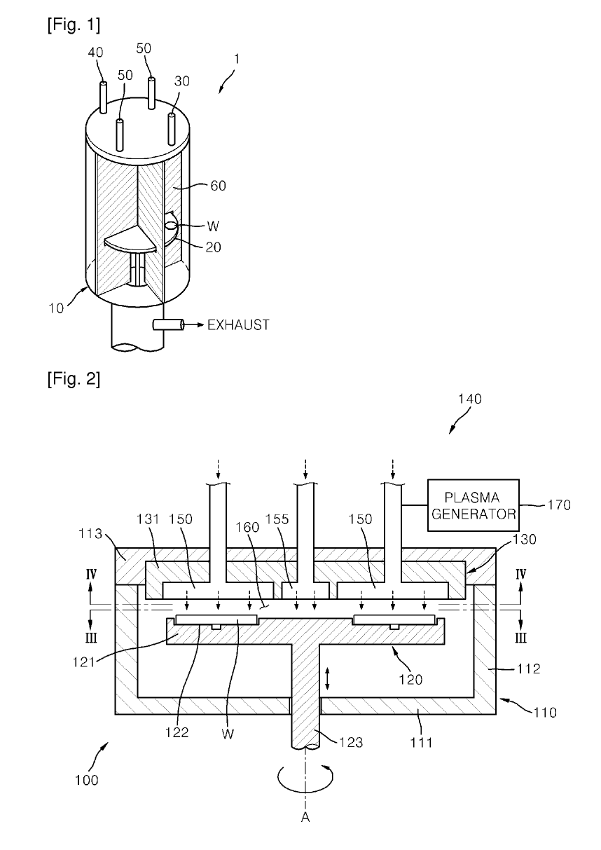

### BEST MODE FOR CARRYING OUT THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

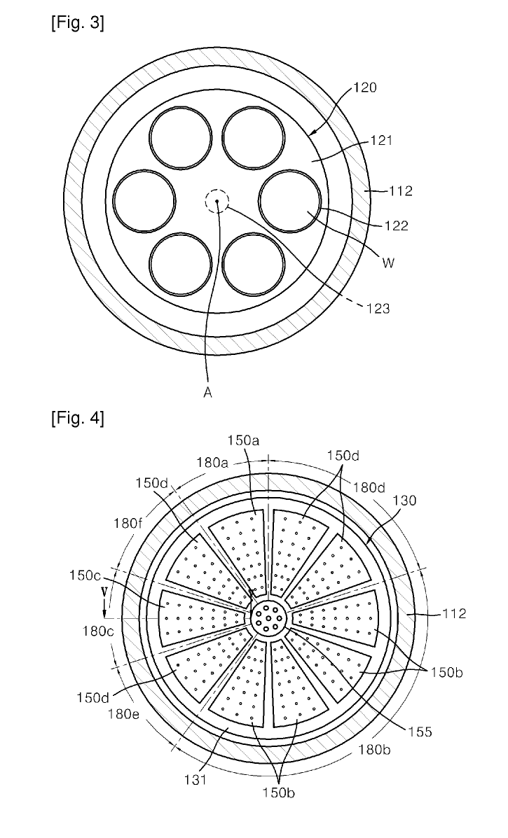

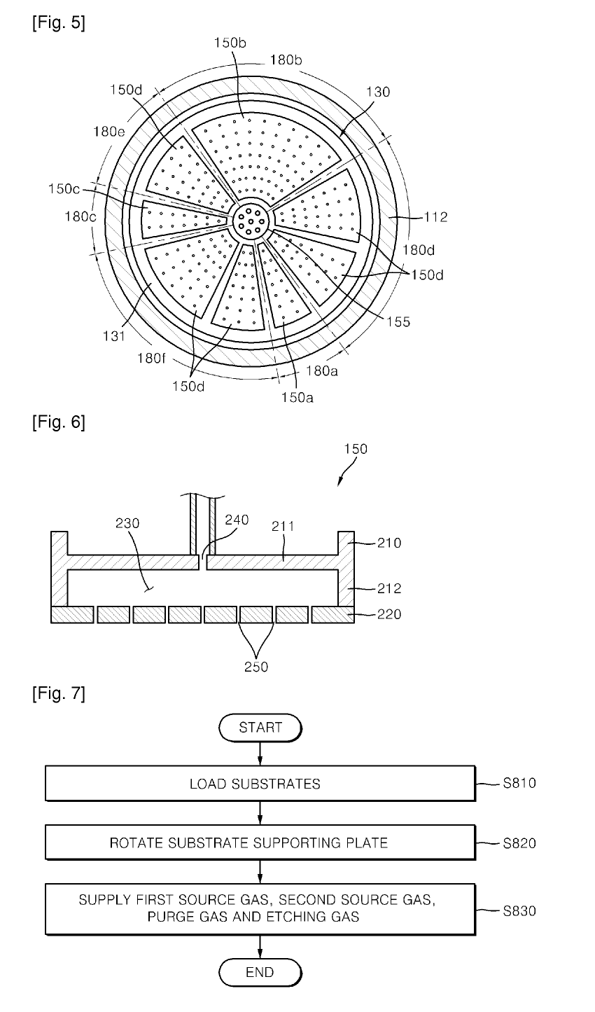

FIG. 2 is a schematic view of an apparatus for depositing a thin film according to an embodiment of the present invention, FIG. 3 is a sectional view taken along line III-III of FIG. 2, FIGS. 4 and 5 are sectional views taken along line IV-IV of FIG. 2, and FIG. 6 is a sectional view taken along line V-V of FIG. 4.

Referring to FIGS. 2 to 6, the apparatus for depositing a thin film according to an embodiment of the present invention includes a reactor 110, a substrate supporting plate 120, a gas injection assembly 130, and a plasma generating unit 140.

The reactor 110 includes a bottom 111, a sidewall 112, and an upper plate 113. The bottom 111 has a circular plate shape, the sidewall 112 is shaped as a cylinder which extends vertically upward from the perimeter of the bottom 111. The sidewall 112 has a transfer passage (not shown) through which a substrate W is loaded or unloaded. The upper plate 113 has a circular plate shape, and is detachably coupled to an upper end of the sidewall 112. When the upper plate 113 is coupled to the upper end of the sidewall 112, a space is formed in the reactor 110. A sealing member, such as an O-ring, is interposed between a bottom surface of the upper plate 113 and the upper end of the sidewall 112 to seal the space defined in the reactor 110. An exhaust (not shown) for exhausting unnecessary gas and particles remaining in the reactor 110 is provided in the bottom 111 or the sidewall 112.

A thin film deposition space 160 is formed above the substrate supporting plate 120 between the substrate supporting plate 120 and the gas injection assembly 130. A thin film is formed on the substrate W by depositing a thin film with a first source gas and a second source gas in the thin film deposition space 160, and the deposited thin film is then etched using an etching gas.

The substrate supporting plate 120 is provided in the reactor 110, and includes a susceptor 121, a substrate loading part 122, a shaft 123, and a heater (not shown).

The susceptor 121 is formed as a circular plate and is rotatably disposed in the reactor 110. The substrate loading part 122 formed in the susceptor 121 is provided in sextuplet, which will be described below. As shown in FIG. 3, the substrate loading parts 122 are arranged circumferentially on the substrate supporting plate 120, and substrates W are loaded on the respective substrate loading parts 122. A lift pin (not shown) ascending and descending in a vertical direction is installed in each of the substrate loading parts 122.

One end of the shaft 123 is coupled to a bottom surface of the susceptor 121, and the other end of the shaft 123 penetrates the reactor 110 and is connected to a rotation driving means. Accordingly, as the shaft 123 rotates, the susceptor 121 rotates about a rotation center axis A represented by the broken line in FIG. 2. Also, the shaft 123 is connected to an ascending and descending driving means that can elevate and lower the susceptor 121. The rotation driving means and the ascending and descending driving means may include a motor, a gear or the like. The heater (not shown) is buried below the susceptor 121 to control the temperature of the substrate W.

The gas injection assembly 130 is coupled to the upper plate 113 of the reactor 110 provided over the substrate supporting plate 120, and includes an upper plate 131 for coupling gas injection units 150. The gas injection units 150 may be classified into a first source gas injection unit 150a, a second source gas injection unit 150b, an etching gas injection unit 150c and a purge gas injection unit 150d, according to the types of supply gases. The first source gas injection unit 150a supplies a first source gas, such as silane (SiH₄), onto the substrate supporting plate 120, and the second source gas injection unit 150b supplies a second source gas, such as oxygen (O₂), onto the substrate supporting plate 120. The etching gas injection unit 150c supplies an etching gas, such as CF₄, onto the substrate supporting plate 120. The purge gas injection unit 150d supplies a purge gas for purging the first source gas, the second source gas and the etching gas onto the substrate supporting plate 120. The purge gas may be an inert gas, such as Ar.

Herein, the purge gas is supplied to prevent the first source gas, the second source gas and the etching gas supplied through the gas injection assembly 130 from mixing. The first source gas, the second source gas and the etching gas may mix at a central portion of the substrate supporting plate 120. Accordingly, it is necessary to provide a means for preventing the first source gas, the second source gas and the etching gas from mixing at the central portion of the substrate supporting plate 120.

In a preferred embodiment, as shown in FIGS. 2, 4 and 5, a central purge gas injection unit 155 for supplying a purge gas (for purging the first source gas, the second source gas and the etching gas) onto the substrate supporting plate 120 is installed at a central portion of the gas injection assembly 130. The purge gas supplied by the central purge gas injection unit 155 prevents the first source gas, the second source gas and the etching gas from being mixed at the central portion of the substrate supporting plate 120.

A sectional view taken along line IV-IV of FIG. 2 is shown in FIG. 4 as a preferred embodiment of the gas injection assembly 130 in the apparatus for depositing a thin film according to the present invention. As shown in FIG. 4, the central purge gas injection unit 155 is disposed at the central portion of the gas injection assembly 130, and the first source gas injection unit 150a, the second gas injection unit 150b, the etching gas injection unit 150c and the purge gas injection unit 150d are disposed radially about the central purge gas injection unit 155.

The ten gas injection units 150 shown in FIG. 4 consist of one first source gas unit 150a, four second source gas units 150b, one etching gas injection unit 150c, and four purge gas injection units 150d. The one first source gas injection unit 150a forms a first source gas injection block 180a, the four second source gas injection units 150b that are adjacent to one another form a second source gas injection block 180b, and the one etching gas injection unit 150c forms an etching gas injection block 180c. Of the four purge gas injection units 150d, two of the purge gas injection units 150d between the first source gas injection block 180a and the second source gas injection block 180b are adjacently disposed to form a purge gas injection block 180d. One of the purge gas injection units 150d between the second source gas injection block 180b and the etching gas injection block 180c forms a purge gas injection block 180e, and the remaining purge gas injection unit 150d between the first source gas injection block 180 and the etching gas injection block 180c forms a purge gas injection block 180f. Resultantly, a total of three purge gas injection blocks 180d, 180e and 180f are formed. That is, in the gas injection assembly 130 shown in FIG. 4, one first source gas injection block 180a, one second source gas injection block 180b, and one etching gas injection block 180c are formed, and three purge gas injection blocks (180d, 180e and 1800 are formed.

For each full rotation of the substrate supporting plate 120 on which the substrate W is loaded below the above-configured gas injection assembly 130, one deposition and one etching are performed. The atomic layer deposition process is performed while the rotating substrate W is sequentially exposed to the first source gas, the purge gas, the second source gas and the purge gas, which are supplied at predetermined time intervals. Some of the deposited thin film is etched while the substrate W passes below the etching gas injection unit 150c of the gas injection assembly 130. In particular, a prominent deposition portion is first etched. Accordingly, when several tens of etching cycles are performed, step coverage of the formed thin film is enhanced.

The embodiment shown in FIG. 4 is preferred when a saturation time of the second source gas is longer than that of the first source gas and the exhaust of the first source gas is not good. The second source gas having a longer saturation time than the first source gas is supplied through the second source gas injection block 180b grouping four of the second source gas injection units 150b. In other words, by increasing an area where the second source gas having the longer saturation time is injected, the efficiency is enhanced. Since the exhaust of the first source gas is not good, two of the purge gas injection units 150d for injecting purge gas to be supplied onto the substrate supporting plate 120 by the rotation of the substrate supporting plate 120 after the injection of the first source gas is grouped to form one purge gas injection block 180d. By doing so, a larger purge gas injection area can be obtained, so that the exhaust of the first source gas becomes smooth and the efficiency is enhanced. Thus, in consideration of saturation times and exhaust rates of the respective source gases, when the gas injection units 150 are properly grouped to form one gas injection block, it is possible to deposit a thin film without waste of the source gases even without changing the rotating rate of the substrate supporting plate 120 or stopping the supply of a specific gas.

For ALD, it is required to prevent the first source gas, the second source gas and the etching gas from being mixed such that these gases do not react in a vapor phase. Accordingly, as shown in FIG. 4, the purge gas injection block 180d is disposed between the first source gas injection block 180a and the second source gas injection block 180b, the purge gas injection block 180e is disposed between the second source gas injection block 180b and the etching gas injection block 180c, and the purge gas injection block 180f is disposed between the etching gas injection block 180c and the first source gas injection block 180a. However, in the case of depositing a thin film using a cyclic CVD method, the purge gas may not be supplied into the purge gas injection block 180d between the first source gas injection block 180a and the second source gas injection block 180b.

Meanwhile, the gas injection assembly 130 of the apparatus 100 for depositing a thin film according to another embodiment of the present invention may have a different gas injection area than that of FIG. 4. Such a construction is shown in FIG. 5. Like in FIG. 4, FIG. 5 is taken along line IV-IV of FIG. 2.

The eight gas injection units 150 shown in FIG. 5 consist of one first source gas unit 150a, one second source gas units 150b, one etching gas injection unit 150c, and five purge gas injection units 150d. The one first source gas injection unit 150a, the one second source gas injection unit 150b and the one etching gas injection unit 150c form one first source gas injection block 180a, one second source gas injection block 180b and one etching gas injection block 180c, respectively. Of the five purge gas injection units 150d, two of the purge gas injection units 150d between the first source gas injection block 180a and the second source gas injection block 180b are adjacently disposed to form a purge gas injection block 180d. One of the purge gas injection units 150d between the second source gas injection block 180b and the etching gas injection block 180c forms a purge gas injection block 180e, and the remaining two purge gas injection units 150d between the first source gas injection block 180a and the etching gas injection block 180c are adjacently disposed to form a purge gas injection block 180f. Resultantly, a total of three purge gas injection blocks 180d, 180e and 180f are formed in the gas injection assembly 130.

The above-mentioned embodiment is useful when the saturation time of the second source gas is short.

While the above embodiment describes that two source gases of the first source gas and the second source gas are employed to deposit a thin film, it will be apparent to be skilled in the art that the types of source gases may be three or more and thus the gas injection assembly 130 may be configured to include at least a first source gas injection unit, a second source gas injection unit and a third gas injection unit.

The gas injection unit 150 may be made in the shape of a showerhead as shown in FIG. 6. The first source gas injection unit 150a, the second source gas injection unit 150b, the etching gas injection unit 150c and the purge gas injection unit 150d have the same mechanical construction except that the types of supply gases are different.

Referring to FIG. 6, the gas injection unit 150 includes a main body 210 and a gas injection plate 220. The main body 210 includes a lid plate 211 having a fan shape, and a sidewall 212, which extends downward from the perimeter of the lid plate 211. The lid plate 211 has a gas supply hole 240 penetrating therethrough such that a gas is introduced thereinto.

The gas injection plate 220 has a fan shape and is coupled to a bottom of the sidewall 212. The gas injection plate 220 has a plurality of injection holes 250 penetrating therethrough such that a gas is injected downward. Inside the gas injection unit is formed a gas diffusion space 230 surrounded by the lid plate 211 of the main body 210, the sidewall 212 of the main body 210 and the gas injection plate 220 to diffuse the supplied gas.

The central purge gas injection unit 155 has the same construction as the gas injection unit 150 except that its gas injection plate and upper plate of the main body have a circular plate shape.

While the above embodiment shows and describes that two or more gas injection units having the construction of FIG. 6 are coupled to the upper plate 131 of the gas injection assembly 130, the present invention is not limited thereto. For example, the gas injection assembly 130 may be configured to include a plurality of gas supply holes 240, a circular plate-shaped upper plate 131 corresponding to the aforementioned lid plate 211, and two or more gas injection plates 220 having a fan shape. One gas diffusion space 230 is formed between the upper plate 131 and one of the two or more gas injection plates 220. Two or more gas diffusion spaces 230 corresponding to the two or more gas injection plates 220 are separated by the gas injection plates 220 and/or the upper plate 131. A portion corresponding to the fan-shaped gas injection plate 220 is the gas injection unit 150.

The plasma generating unit 140 changes the etching gas into plasma and supplies the plasma to the reactor 110. In addition to the etching gas, the plasma generating unit 140 may have a means to change the first source gas, the second source gas and the purge gas into plasma. In this embodiment, the plasma generating unit 140 may have a plasma generator 170 as a means for generating plasma. The plasma generator 170 is a remote plasma generator, which is installed outside the reactor 110. The plasma generator 170 is connected to the gas injection assembly 130, and in a thin film forming process, receives an RF power to change a gas into plasma and supply the plasma to the reactor 110.

In addition to the above-described construction that the plasma generator 170 changes a gas into plasma and supplies the plasma to the reactor 110, plasma may be generated inside the gas injection assembly 130 and supplied onto the substrate supporting plate 120. In this case, plasma may be generated in all of the inside of the gas injection assembly 130 and supplied onto the substrate supporting plate 120, or in some of the inside of the gas injection assembly 130 and supplied onto the substrate supporting plate 120. Alternatively, plasma may be generated in a space (e.g., a thin film deposition space 160 in this embodiment) between the gas injection assembly 130 and the substrate supporting plate 120 by applying a power to the gas injection assembly 130 or the substrate supporting plate 120. Likewise, plasma may be generated in all of the space between the gas injection assembly 130 and the substrate supporting plate 120, or in some of the space between the gas injection assembly 130 and the substrate supporting plate 120.

FIG. 7 is a flowchart for describing a method for depositing a thin film according to an exemplary embodiment. For reference, it will be described that methods for depositing a thin film to be described below can be realized using the apparatus 100 for depositing a thin film according to the present invention. However, another apparatus other than the apparatus may be used for these methods if an operation of rotating the substrate supporting plate can be embodied such that two or more substrates are sequentially exposed to the first source gas injection block, the purge gas injection block, the second gas injection block, the purge gas injection block, the etching gas injection block, and the purge gas injection block, which are radially arranged. For example, while the thin film depositing apparatus 100 shown in FIG. 2 is configured to include the gas injection block 180 made in the showerhead type, thin film depositing methods according to the present invention may be embodied by using an apparatus having gas injectors arranged radially.

Referring to FIGS. 2 and 7, in operation S810, a plurality of substrates W are loaded on the substrate loading part 122 of the substrate supporting plate 120 installed in the reactor 110. In operation S820, the temperatures of the substrates W are adjusted to a process temperature using the heater, and the substrate supporting plate 120 is rotated such that the plurality of substrates W are sequentially exposed to the first source gas injection block 180a, the purge gas injection block 180d, the second source gas injection block 180b, the purge gas injection block 180e, the etching gas injection block 180c and the purge gas injection block 180f arranged sequentially and radially. Only an etching gas, which is changed into plasma, may be first supplied to remove a native oxide formed on the substrates W.

In operation S830, the first source gas, the second source gas, the purge gas and the etching gas are supplied through together the respective gas injection blocks 180a-180f to form a thin film. Thus, atomic layer deposition is performed by rotating the substrate supporting plate 120 such that the substrates W on the substrate loading part 122 of the substrate supporting plate 120 pass below the first source gas injection block 180a, the purge gas injection block 180d, the second source gas injection block 180b and the purge gas injection block 180e at predetermined time intervals. While the substrates W pass below the etching gas injection block 180c, some of the deposited atomic layer is etched. Thus, when a thin film is formed by concurrently performing deposition and etching in the above manner, the thin film can be formed with good gap-fill capability.

Since the etching may be not necessary in all cycles, the supply of the etching gas may be stopped for a predetermined time. Meanwhile, after the deposition of the thin film is completed, the thin film may be deposited on an inner surface of the reactor 110. Therefore, after a predetermined number of processes are completed, a cleaning gas may be supplied into the inside of the reactor 110 in order to perform an in-situ cleaning. The cleaning gas may be an etching gas or purge gas changed to plasma. By constituting each of the gas injection blocks 180a-180f in a showerhead type, flow control is easy and uniformity of a deposited layer can be enhanced.

According to the types of source gases and a recipe, the saturation times of the source gases may be different. In this case, if the recipe is set to match with the source gas having the longest saturation time, waste of source gas may occur and the productivity may be lowered. These issues may be solved by adjusting the rotating rate of the substrate supporting plate 120 or stopping the supply of a source gas having a short saturation time using a valve. However, the above solutions make the process complicated, which is not preferable. Accordingly, to address the above problems, the gas injection area of one having a longer saturation time of the first source gas and the second source gas may be increased or the flow rate of one having a longer saturation time of the first source gas and the second source gas may be increased.

The first source gas, the second source gas and the purge gas may be changed into plasma for deposition of a thin film. The plasma used for changing the first source gas, the second source gas and the purge gas into plasma may be a remote plasma or a plasma generated from each of the gas injection blocks 180a-180f. The plasma used for changing the first source gas, the second source gas and the purge gas into plasma is a direct plasma generated when a power is supplied to the gas injection blocks 180a-180f or the substrate supporting plate 120. The plasma used in this case is a plasma generated in an entire space or some space between the respective gas injection blocks 180a-180f and the substrate supporting plate 120.

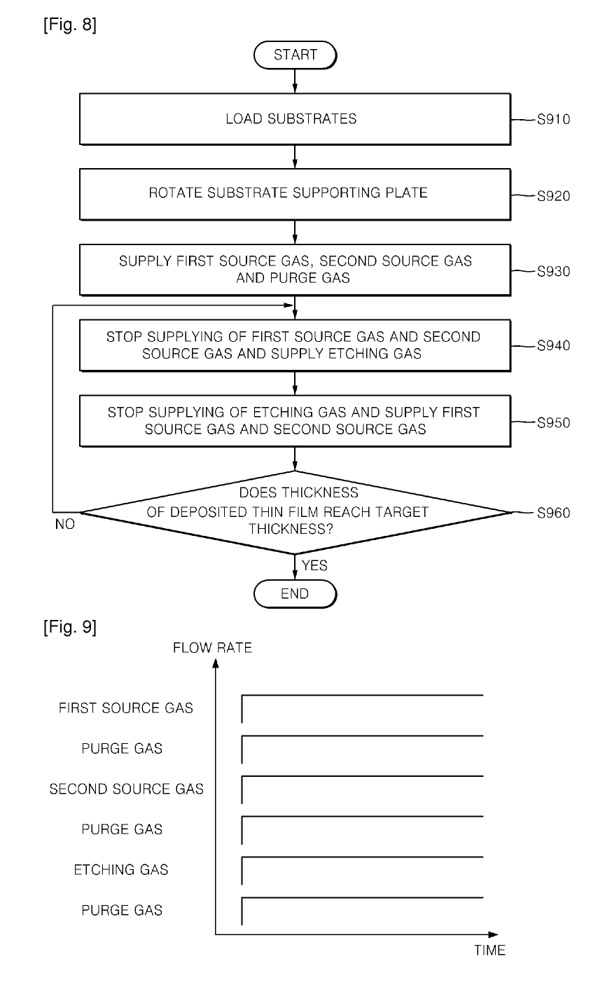

FIG. 8 is a flowchart illustrating a method for depositing a thin film according to another exemplary embodiment. For reference, it will be described that methods for depositing a thin film to be described below can be realized using the apparatus 100 for depositing a thin film according to the present invention. However, another apparatus other than the apparatus may be used for these methods if an operation of rotating the substrate supporting plate can be embodied such that two or more substrates are sequentially exposed to the first source gas injection block, the purge gas injection block, the second gas injection block, the purge gas injection block, the etching gas injection block, and the purge gas injection block, which are radially arranged. For example, while the thin film depositing apparatus 100 shown in FIG. 2 is configured to include the gas injection block 180 made in the showerhead type, thin film depositing methods according to the present invention may be embodied by using an apparatus having gas injectors arranged radially.

Referring to FIGS. 2 and 8, in operation S910, a plurality of substrates W are loaded on the substrate loading part 122 of the substrate supporting plate 120 installed in the reactor 110. In operation S920, the temperatures of the substrates W are adjusted to a process temperature using the heater, and the substrate supporting plate 120 is rotated such that the plurality of substrates W are sequentially exposed to the first source gas injection block 180a, the purge gas injection block 180d, the second source gas injection block 180b, the purge gas injection block 180e, the etching gas injection block 180c and the purge gas injection block 180f arranged sequentially and radially. Only an etching gas, which is changed into plasma, may be first supplied to remove a native oxide formed on the substrates W.

In operation S930, the supply of the etching gas is stopped, and the first source gas, the second source gas and the purge gas are supplied onto the substrate supporting plate 120 together through the first source gas injection block 180a, the purge gas injection block 180d, the second source gas injection block 180b and the purge gas injection block 180e to form a thin film. As aforementioned, atomic layer deposition is performed by rotating the substrate supporting plate 120 such that the substrates W on the substrate loading part 122 of the substrate supporting plate 120 pass below the first source gas injection block 180a, the purge gas injection block 180d, the second source gas injection block 180b and the purge gas injection block 180e at predetermined time intervals.

In operation S940, after a thin film is deposited at a predetermined thickness, the supply of the first source gas and the second source gas is stopped, and the etching gas changed into plasma is supplied through the etching gas injection block 180c. At this time, the purge gas continues to be supplied. In operation 950, after the thin film is etched for a predetermined time, the supply of the etching gas is stopped and the first source gas and the second source gas are supplied onto the substrate supporting plate 120 together through the first source gas injection block 180a and the second source gas injection block 180b to deposit a thin film. At this time, the purge gas continues to be supplied.

In operation S960, it is determined whether the thin film is deposited to a desired thickness. When it is determined that the thin film does not reach a desired thickness, operations S940 and S950 are repeated until the thin film is deposited at a desired thickness. Thus, in the case that a thin film is formed by alternatively repeating the operation of supplying only the source gases without any supply of an etching gas and the operation of supplying only the etching gas without the supply of the source gases, the formed thin film may have superior gap-fill capability.

In this embodiment, after a predetermined number of processes are completed, an in-situ cleaning of inside of the reactor 110 may be performed using a cleaning gas. The first source gas, the second source gas or the purge gas may be changed to plasma for the deposition of the thin film. The used plasma may be a remote plasma or a plasma generated in an inside of each of the gas injection blocks 180a-180f or a direct plasma generated when a power is supplied to the gas injection blocks 180a-180f or the substrate supporting plate 120. Also, to prevent waste of the source gases and increase the productivity, it is preferable that the gas injection area of one having a longer saturation time of the first source gas and the second source gas is increased or the flow rate of one having a longer saturation time of the first source gas and the second source gas is increased.

FIGS. 9 through 11 are graphs showing flow rates of the first source gas, the second source gas, the etching gas and the purge gas versus time in a method for depositing a thin film according to the present invention.

FIG. 9 is a graph showing flow rates of supply gases versus time in a method for depositing a thin film in which deposition and etching of the thin film are concurrently performed by supplying the first source gas, the second source gas, the etching gas and the purge gas together with respect to all time scales. Thus, forming of a thin film by concurrently performing deposition and etching is to deposit a thin film with superior cap-fill capability.

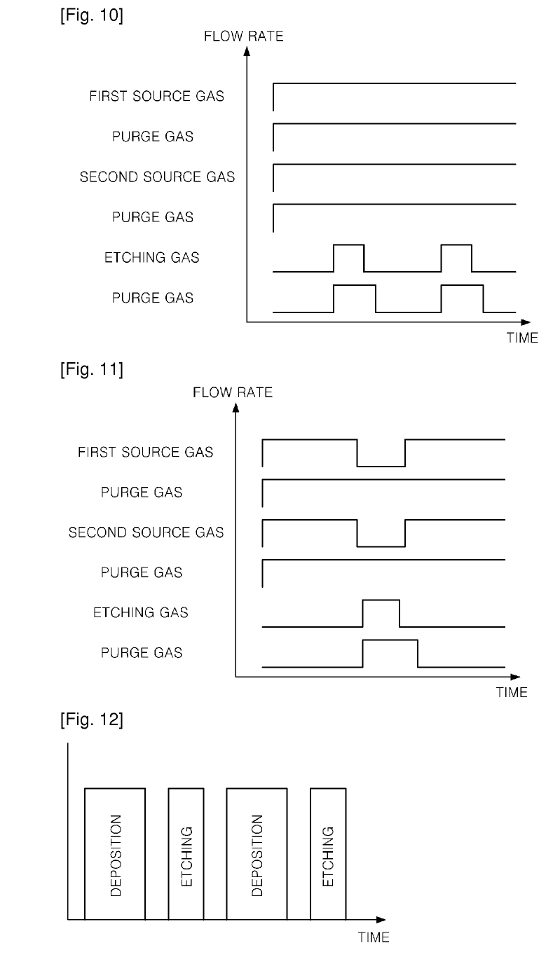

FIG. 10 is a graph showing flow rates of supply gases versus time in a method for depositing a thin film in which the first source gas and the second source gas continue to be supplied and the etching gas and the purge gas for purging the etching gas are periodically supplied. In other words, in this method, deposition is only performed without supply of the etching gas during a few or a few ten cycles, and deposition and etching are concurrently performed with the supply of the first source gas, the second source gas and the etching gas during a few cycles. This method corresponds to a case where the etching rate is higher than the deposition rate or a case where the thin film has good gap-fill capability even when the thin film is not etched in each cycle. In this embodiment, it is preferable that even when the supply of the etching gas is stopped, the purge gas for purging the etching gas is further supplied for a predetermined time, which is to prevent the etching gas and the source gases from mixing.

FIG. 11 is a graph showing flow rates of supply gases versus time in a method for depositing a thin film in which deposition during a few or a few ten cycles and etching during a few cycles are alternatively performed. The deposition of the thin film is performed by supplying the first source gas and the second source gas without the supply of the etching gas, and the etching is performed by supplying the etching gas without the supply of the first source gas and the second source gas. The method of alternatively supplying the source gases and the etching gas to form a thin film, i.e., the method of forming a thin film by stopping the supply of the etching gas during a few cycles to perform only the deposition and then stopping the supply of the source gases to perform only the etching, and repeating these operations, is advantageous for a process control. In this case, it is of course that a thin film with good gap-fill capability can be formed. In this embodiment, it is preferable that after the supply of the etching is stopped, the purge gas for purging the etching gas is further supplied for a pre-determined time.

Thus, it is possible to form a thin film with good gap-fill capability by properly adjusting the flow rates of the first source gas, the second source gas, the etching gas and the purge gas according to the types of the source gases and the etching gas and the recipe to alternatively perform deposition and etching.

FIG. 12 is a graph showing a thin film forming process in which deposition and etching are alternatively performed. From the graph of FIG. 12, it will be understood that a thin film is formed by depositions during predetermined time periods and etchings during predetermined time periods.

The thin film forming method of FIG. 12 may be used for depositing a SiO₂ layer. In this case, the first source gas may be a silicon-containing source, for example, one selected from the group consisting of silane (SiH₄), TEOS (Tetra ethyl ortho silicate), TEMASi (Tetra ethyl methyl amino silicon), TMDSO (Tetra methyl disiloxane) and HMDSO (Hexa methyl disiloxane). The second source gas may be an oxygen-containing gas, for example, at least one selected from the group consisting of N₂O, H₂O, O₂ and O₃. The etching gas may be at least one selected from the group consisting of Ar, CF₄, CHF₃, CH₂F₂, C₂F₈, C₃F₈, D₄F₈, SF₆, NF₃ and C₄F₆.

In addition to the silicon oxide (SiO₂), the aforementioned thin film forming method may be used for forming a high dielectric constant oxide having a higher dielectric constant than silicon oxide, silicon nitride (Si₃N₄), and polysilicon (poly Si). The above method may be also used for depositing a metal layer, such as Cu, W or the like, or a metal nitride layer, such as TiN.

The aforementioned thin film forming method according to the present invention is particularly useful in depositing an oxide layer or a nitride layer on a substrate having a trench or gap having a high aspect ratio in manufacturing a semiconductor device.

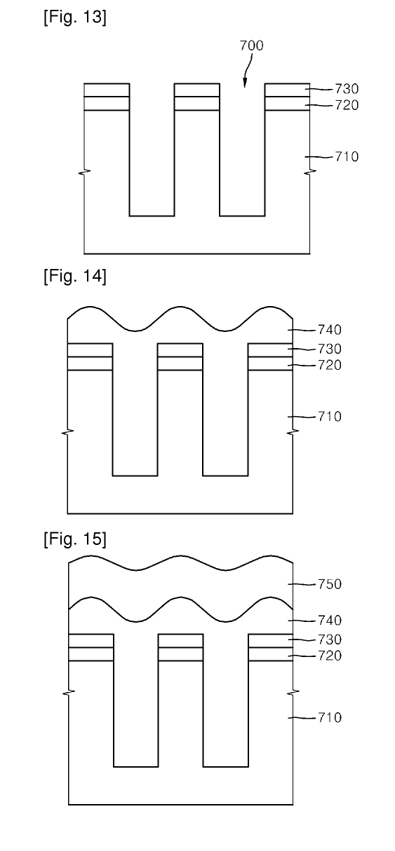

FIGS. 13 through 16 are sectional views illustrating operations of forming a trench on a substrate and gap-filling the trench.

A pad oxide layer 720 and a nitride layer 730 are formed on a silicon substrate 710, and are selectively etched to form a trench mask. Then, the silicon substrate 710 is dry-etched using the patterned nitride layer as an etch mask to form a trench 700 shown in FIG. 13.

Next, an oxide layer 740 is formed in the trench 700 using the aforementioned thin film forming method to gap-fill the trench 700 as shown in FIG. 14. The aforementioned thin film forming method may be used for forming the oxide layer 740 in the trench 700. That is, deposition and etching are concurrently or alternatively performed by supplying an oxide forming source as a first source gas, an oxygen-containing reaction gas as a second source gas, and an oxide etching gas as an etching gas. While the trench 700 is gap-filled, the deposition at a corner is precisely controlled to prevent an overhang. According to the progressive degree of the gap-fill, the supply of the etching gas may be controlled to enhance the gap-fill speed.

After the deposition of the oxide layer 740 in the trench or gap formed on the substrate is completed as shown in FIG. 15, an additional oxide layer 750 is deposited on the oxide layer 740. At this time, it is possible to enhance the deposition rate of the additional oxide layer 750 by supplying only the source gases without the supply of the etching gas.

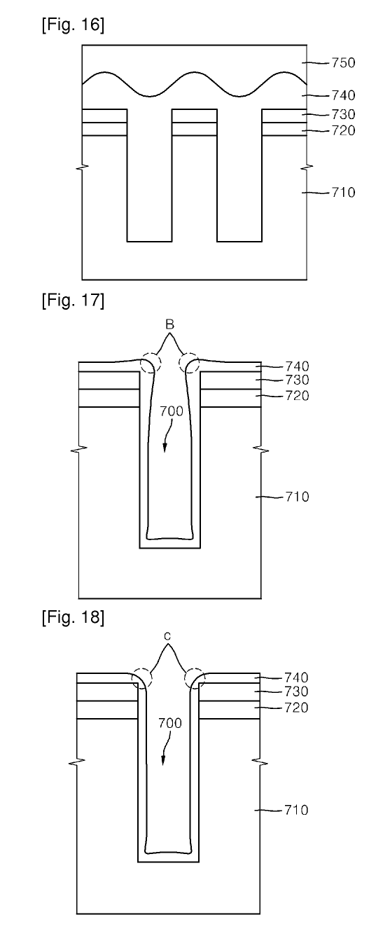

After the deposition of the additional oxide layer 750 is completed as shown in FIG. 16, a chemical mechanical polishing (CMP) is performed to planarize the resultant substrate.

While the present embodiment shows and describes the method of gap-filling the trench 700 with the oxide layer, it will be appreciated that the method may be applied to the case of a nitride layer. In the case of a nitride layer, a nitride layer forming source gas as a first source gas, a nitrogen-containing reaction gas as a second source gas, and a nitride etching gas as an etching gas are supplied to perform the thin film forming method according to the present invention. Also, the above method may be employed for a gap, which is formed between metal interconnection lines.

Furthermore, the aforementioned method may be employed for a case of gap-filling a contact hole or via-hole with a metal layer or metal nitride layer. At this time, a metal source gas as a first source gas, a reaction gas as a second source gas, and a metal etching gas or metal nitride etching gas as an etching gas are supplied to perform the thin film forming method according to the present invention.

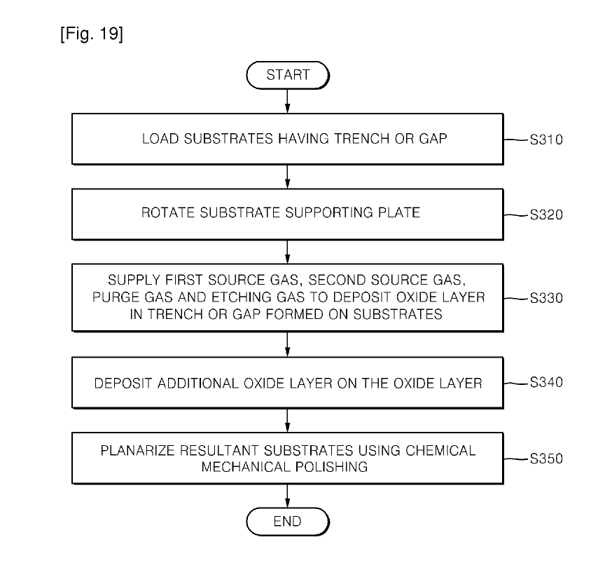

FIGS. 17 and 18 are sectional views illustrating processes of forming a thin film with good gap-fill capability by controlling a trench corner portion using an etching in gap-filling a thin film forming method according to the present invention.

A gap-fill oxide layer is formed in a trench 700 using the thin film forming method according to the present invention. If the gap-fill oxide layer is deposited by supplying only a first source gas and a second source gas without the supply of an etching gas, an overhang may be generated at a corner portion B of the trench 700 as shown in FIG. 17. Although the aforementioned thin film forming method makes it possible to perform ALD, some overhang may be generated in the case of the trench 700. Then, in the case of the trench 700 having a very high aspect ratio, some overhang causes voids or seam to be generated, so that the gap-fill process may not be smoothly performed. In the aforementioned thin film depositing method, if the purge gas is not supplied between the supply periods of the source gases, a thin film is deposited by a cyclic CVD, which may cause an overhang issue.

At this time, since the supply of the etching gas increases the etching selectivity in the corner portion C to over-etch the corner portion C, overhang is not generated. Thus, by concurrently or alternatively performing deposition and etching using the thin film depositing method according to the present invention, overhang can be controlled, thereby depositing a thin film with good gap-fill capability.

FIG. 19 is a flowchart illustrating an embodiment of a gap-fill method for a semiconductor device using a thin film depositing method according to the present invention.

Referring to FIG. 19, in operation S310, a plurality of substrates W each having a trench 700 or gap formed thereon are loaded on the substrate loading part 124 of the substrate supporting plate 120 installed in the reactor 110. In operation S320, the temperature of the plurality of substrates W is adjusted to a process temperature using a heater, and then the substrate supporting plate 120 is rotated such that the plurality of substrates W are exposed to the first source gas injection block 180a, the purge gas injection block 180d, the second source gas injection block 180b, the purge gas injection block 180e, the etching gas injection block 180c and the purge gas injection block 180f, which are arranged sequentially and radially. Next, only the etching gas changed into plasma may be first supplied to remove a native oxide formed on the plurality of substrates W.

Next, in operation S330, the first source gas, the second source gas, the purge gas and the etching gas are concurrently or alternatively supplied through the respective gas injection blocks 180a-180f to deposit an oxide layer 740 in the trench or gap formed on the plurality of substrates W. The oxide layer 740 for the gap-fill is formed using the aforementioned thin film depositing method such that overhang is not generated at corners B, C of the trench 700 or gap. In operation S340, an additional oxide layer 750 is deposited on the oxide layer 740. At this time, only the source gases are supplied without the supply of the etching gas.

In operation S350, a CMP is performed to planarize the resultant substrates.

Although the apparatus and method for depositing a thin film on a wafer and the method for gap-filling a trench have been described with reference to the specific embodiments, they are not limited thereto. Therefore, it will be readily understood by those skilled in the art that various modifications and changes can be made thereto without departing from the spirit and scope of the present invention defined by the appended claims.

For example, although the embodiments describe that ALD is performed by sequentially supplying the source gas and the purge gas, they may be modified to have a construction in which the purge gas injection block is installed but the purge gas is not supplied. For example, it is also possible to realize a cyclic CVD by setting the gas supply cycle in the order of the first source gas supply, the second source gas supply (and the etching gas supply).

1. An apparatus for depositing a thin film comprising:
a reactor; and
a plurality of substrates provided on the same space inside the reactor,
wherein deposition of the thin film and partial etching of the deposited thin film are repeated to form the thin film on the plurality of substrates by exposing the plurality of substrates to two or more source gases and an etching gas supplied together at time intervals while rotating the plurality of substrates.

2. The apparatus of claim 1, wherein the apparatus comprises:
a substrate supporting plate provided with a plurality of substrate loading parts on which the plurality of substrate are loaded, and rotatably installed inside the reactor; and
a gas injection assembly provided over the substrate supporting plate in the reactor to inject a gas onto the substrate supporting plate and including a plurality of gas injection units arranged radially,
wherein the plurality of gas injection units comprise at least one first source gas injection unit configured to inject a first source gas onto the substrate supporting plate, at least one second source gas injection unit configured to inject a second source gas that is different from the first source gas onto the substrate supporting plate, at least one etching gas injection unit configured to inject an etching gas for etching a thin film deposited by the first source gas and the second source gas onto the substrate supporting plate, and at least one purge gas injection unit configured to inject a purge gas for purging the first source gas, the second source gas and the etching gas onto the substrate supporting plate.

3. The apparatus of claim 2, wherein each of the plurality gas injection units comprises:
a main body having a gas supply hole through which a gas is supplied; and
a gas injection plate installed in the main body to be spaced apart by a pre-determined distance downward with respect to an upper surface of the main body such that the gas injection plate forms a gas diffusion space in which the gas supplied through the gas supply hole is diffused, together with the main body, the gas injection plate having a plurality of injection holes penetrating an upper surface and a lower surface thereof such that the gas is injected downward.

4. The apparatus of claim 2, wherein of the first source gas injection units of the gas injection assembly, one or at least two adjacently disposed and grouped form a first source gas injection block, of the second source gas injection units of the gas injection assembly, one or at least two adjacently disposed and grouped form a second source gas injection block, of the etching gas injection units of the gas injection assembly, one or at least two adjacently disposed and grouped form an etching gas injection block, and of the purge gas injection units, one or two adjacently disposed and grouped form a purge gas injection block.

5. The apparatus of claim 4, wherein the purge gas injection block is respectively provided between the first source gas injection block and the second source gas injection block, between the second source gas injection block and the etching gas injection block and between the etching gas injection block and the first source gas injection block.

6. The apparatus of claim 4, wherein the gas injection assembly further comprises a central purge gas injection unit provided at a central portion of the gas injection assembly to supply a purge gas for purging the first source gas, the second source gas and the etching gas onto the substrate supporting plate,
wherein the respective gas injection blocks are arranged radially about the central purge gas injection unit.

7. The apparatus of claim 4, further comprising a plasma generating unit capable of changing at least one of the first source gas, the second source gas, the etching gas and the purge gas into plasma.

8. The apparatus of claim 7, wherein the plasma generating unit is an apparatus capable of generating plasma inside the gas injection unit.

9. The apparatus of claim 7, wherein the plasma generating unit is an apparatus capable of generating plasma in a portion of an inside of the gas injection assembly

10. The apparatus of claim 7, wherein the plasma generating unit is a remote plasma generator.

11. A method for depositing a thin film comprising:
(a1) loading a plurality of substrates on a substrate supporting plate provided with a plurality of substrate loading parts and rotatably installed inside a reactor;
(a2) rotating the substrate supporting plate such that the plurality of substrates are sequentially exposed to a first source gas injection block, a purge gas injection block, a second source gas injection block, a purge gas injection block, an etching gas injection block and a purge gas injection block, which are arranged radially;
(a3) depositing a thin film by supplying a first source gas, a second source gas, a purge gas and an etching gas onto the substrate supporting plate together through each of the gas injection blocks.

12. The method of claim 11, wherein in the operation (a3), the thin film is deposited by repeating supply and stop of the etching gas.

13. A method for depositing a thin film comprising:
(b1) loading a plurality of substrates on a substrate supporting plate provided with a plurality of substrate loading parts and rotatably installed inside a reactor;
(b2) rotating the substrate supporting plate such that the plurality of substrates are sequentially exposed to a first source gas injection block, a purge gas injection block, a second source gas injection block, a purge gas injection block, an etching gas injection block and a purge gas injection block, which are arranged radially;
(b3) depositing a thin film by supplying a first source gas, a second source gas and a purge gas onto the substrate supporting plate together through the first source gas injection block, the second source gas injection block and the purge gas injection block;
(b4) after the thin film is deposited at a predetermined thickness, stopping the supply of the first source gas and the second source gas, and supplying an etching gas through the etching gas injection block to etch the deposited thin film;
(b5) after an elapse of a predetermined time, stopping the supply of the etching gas and supplying the first source gas and the second source gas onto the substrate supporting plate together through the first source gas injection block and the second source gas injection block to deposit the thin film; and
(b6) sequentially repeating the operation (b4) and the operation (b5) at least once.

14. The method of claim 11 or 12, between the operation (a2) and the operation (a3), further comprising supplying the etching gas through the etching gas injection block without the supply of the first source gas and the second source gas to remove native oxide on the substrate.

15. The method of claim 13, between the operation (b2) and the operation (b3), further comprising supplying the etching gas through the etching gas injection block without the supply of the first source gas and the second source gas to remove native oxide on the substrate.

16. The method of claim 11 or 12, wherein in the operation (a3), at least one of the first source gas, the second source gas, the etching gas and the purge gas are changed into plasma and the changed plasma is supplied onto the substrate supporting plate.

17. The method of claim 13, wherein in the operation (b4), the etching gas is changed into plasma and the changed plasma is supplied onto the substrate supporting plate.

18. The method of claim 13, wherein in the operation (b3) or the operation (b5), at least one of the first source gas, the second source gas and the purge gas are changed into plasma and the plasma is supplied onto the substrate supporting plate.

19. The method of any one of claims 11 to 13, wherein one having a longer saturation time on a surface of the substrate of the first source gas and the second source gas has a higher flow rate than the other.

20. The method of any one of claims 11 to 13, wherein after the thin film is deposited, the inside of the reactor is in-situ cleaned.

21. A method for depositing an oxide layer, a nitride layer, a poly Si layer, and a metal layer according to the method of any one of claims 11 to 13.

22. A method for gap-filling a trench or gap formed on a substrate by depositing a thin film on the substrate using the method of any one of claims 11 to 13,
wherein deposition and etching are concurrently or alternatively performed using an oxide or nitride forming source as the first source gas, an oxygen-containing gas or a nitrogen-containing gas as the second source gas and an oxide or nitride etching gas as the etching gas to form a first oxide layer or first nitride layer in the trench or gap formed on the substrate.

23. The method of claim 22, after the forming of the oxide layer or nitride layer in the trench or gap formed on the substrate, further comprising additionally forming a second oxide layer or second nitride layer on the first oxide layer or first nitride layer without supplying the etching gas.

24. A method for gap-filling a contact hole or via hole formed on a substrate by depositing a thin film on the substrate using the method of any one of claims 11 to 13,
wherein deposition and etching are concurrently or alternatively performed using a metal source gas as the first source gas, a reaction gas as the second source gas and a metal etching or metal nitride etching gas as the etching gas to form a metal layer or metal nitride layer in the contact hole or via hole formed on the substrate.
